(19) United States
(12) Patent Application Publication
(10) Pub. No.: US 2006/0171185 A1
(43) Pub. Date: Aug. 3, 2006

(54) Module for reading data carriers

(75) Inventor: Andreas Lotz, Asslar-Berghausen (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/539,973

(22) PCT Filed: Dec. 9, 2003
(86) PCT No.: PCT/IB03/05754

§ 371 Date: Jan. 17, 2006

(30) Foreign Application Priority Data
Dec. 20, 2002 (EP) 02102847.7

(51) Int. Cl. G11C 7/02; H04B 3/00; B60T 7/12; H05K 11/00

(52) U.S. Cl. 365/53; 701/96; 455/344; 381/77

(57) ABSTRACT

A module for reading data carriers, with a processor arrangement and a reading unit,—wherein the module is designed for incorporation in a data processing device,—wherein addressable coded data are stored on the data carrier, and—wherein the processor arrangement comprises a decoding function and is for this purpose designed for—receiving a request, characterized by an identifier, for decoded data which are stored in coded form on the data carrier,—controlling the reading unit such that the requested data, defined by a start address, are read in the coded form from the data carrier,—converting the coded data into decoded data by means of the decoding function, and—making the decoded data, characterized by the identifier, available.

The invention relates to a module for reading data carriers, with a processor arrangement and a reading unit.

Modules are known which are designed for incorporation in car radios or navigation systems, or combined car radio/navigation systems, and capable of providing these devices with ROM data (for example navigation data) derived from a data carrier, for example a CD-ROM or DVD-ROM. Navigation systems are strongly dependent on data stored in large quantities on a data carrier. In this case, other data stored on the data carrier are frequently required, for example by the navigation system, so as to update the navigation information presented to the user at regular intervals. The module reading the data carrier is connected to the car radio or the navigation system by means of a data/control bus. The data are requested by the car radio/navigation system from the module by means of an address (for example a logic block address—LBA). The data are deposited in the standardized block coding on a CD-ROM. The module then supplies the coded data, and said coded data are decoded in the car radio/navigation system. In a different known embodiment, the requested data are decoded in the module and transmitted via a standardized parallel bus (for example IDE/ATAPI). The decoding is effected by means of a commercially available decoder IC. Since this is a module that has to comply with the stringent requirements of incorporation in a vehicle, such modules typically offer only limited reading speeds, for example 2-fold or 4-fold. Indeed, decoder ICs for low data rates become increasingly expensive because the demand for such components, which are mainly used in computers, becomes ever smaller. 40-fold or 48-fold reading speeds are usual in computers. Furthermore, the large number of connecting lines (the IDE/ATAPI bus has 40 lines) is not welcome in the automotive field, since a large number of lines rather tends to be a weak point in achieving a high connecting reliability in the case of strong impacts and wide temperature fluctuations. Furthermore, each connecting line also represents a cost factor.

It is accordingly an object of the invention to make available an improved module.

This object is achieved by means of a module for reading data carriers, with a processor arrangement and a reading unit,
wherein the module is designed for incorporation in a data processing device,
wherein addressable coded data are stored on the data carrier, and
wherein the processor arrangement comprises a decoding function and is for this purpose designed for
   receiving a request, characterized by an identifier, for decoded data which are stored in coded form on the data carrier,
   controlling the reading unit such that the requested data, defined by a start address, are read in the coded form from the data carrier,
   converting the coded data into decoded data by means of the decoding function, and
   making the decoded data, characterized by the identifier, available.

An advantage of the embodiment of claim 1 is a guaranteed synchronization in that the data made available are characterized by the same identifier as the request for the data. This renders possible a data request for new data while the data made available in response to the old request can be suitably assigned thanks to the old identifier. The module also offers the advantage that the decoding is carried out in the module itself.

An advantage of a further embodiment of the invention lies in the use of a serial bus, which leads to a smaller number of connecting lines (i.e. lower cost), and thus also to an improvement of the connection reliability, because fewer contacting points also represent fewer possibilities of contact losses. Flat cable connections with few contacts are more robust and less sensitive to impacts and temperature fluctuations than are contact foils, which are used for many connecting lines.

A further advantage of the module according to the invention lies in the possibility of loading decoding programs or decompression programs from a memory. In that case, a decompression of compressed audio data sequences (for example MP3 or WMA) as well as a block decoding of ROM data sequences is possible, in dependence on the data sequences stored on the data carrier, because the corresponding program need merely be loaded into the programmable processor.

A further embodiment of the invention offers the possibility of accessing the data of a data carrier from a data processing system (for example a navigation system) in a manner that can be easily implemented. Thus high-level language commands as known from programming languages (for example C or Pascal) can be used for data requests, instead of having to work at the address level. The start address is determined in the module.

Since a navigation system knows where it is geographically (for example through the reception of GPS data), a geographical knowledge of the data on the CD, for example, (i.e. a corresponding nomenclature of the data sequences) will suffice. The navigation system receives the data independently of the CD, on which the data may start at different start addresses in dependence on the update, because the start address of the data is derived from the names of the data sequence and the table of contents information in the module. The names of the data sequences and the start addresses belonging to the data sequences are contained in the table of contents information.

The invention relates also to a data carrier playback device, e.g. a car radio, in which a module as described is incorporated.

The various aspects of the invention will be explained in detail below with reference to embodiments and the drawing, in which:

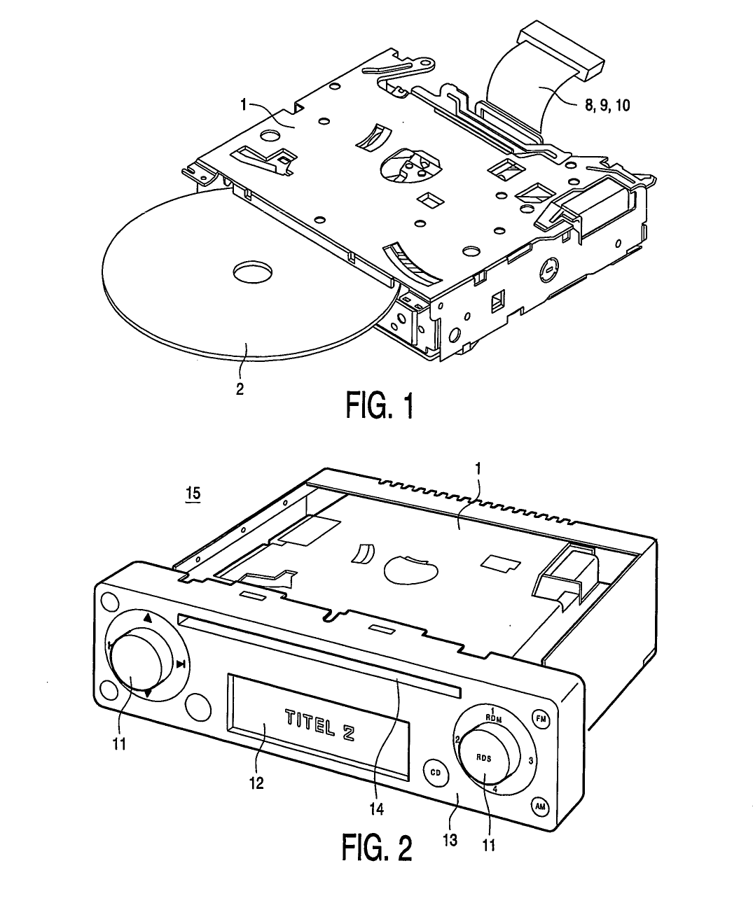

FIG. 1 shows a module for reading data carriers with a CD/DVD in the insertion/ejection compartment,

FIG. 2 shows a car radio which is designed for incorporation in the interior of an automobile and in which a module for reading data carriers is mounted, and

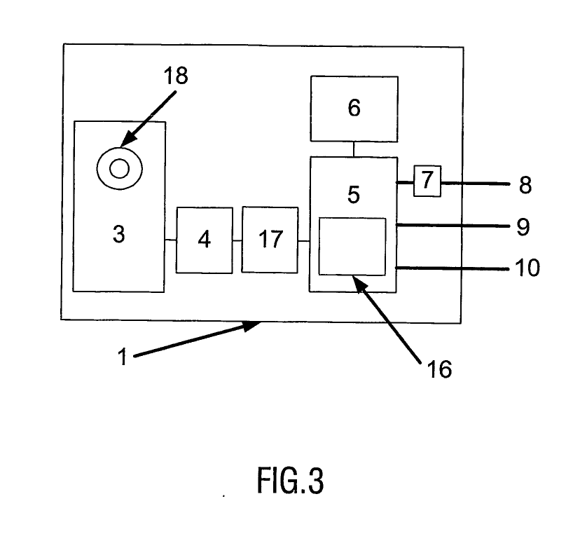

FIG. 3 is a block diagram of the internal construction of the module.

FIG. 1 shows a module 1 for reading data carriers 2, which module has a data carrier 2 in its insertion/ejection compartment. Lines 8, 9, 10 (here shown as a flat cable with a plug connector) are provided for the power supply and data exchange and are coupled to the car radio. The disc-shaped data carrier 2 (a CD/DVD in this case) is transported to a drive unit by mechanical elements (not shown) and is rotated thereon, such that a radially movable data pick-up is capable of reading data sequences present in spiraling structures on the CD/DVD.

FIG. 2 shows a car radio 15 which is designed for incorporation in the instrument panel of an automobile. The car radio 15 has a front 13 with controls 11, a display 12, and a slot 14 corresponding to the insertion/ejection compartment of the module. The module 1 is integrated in the car radio 15, which may be realized by means of screwing or locking or other known mounting methods. A user may carry out simple or complicated operational actions by means of the controls 11, which then leads to an exchange of commands from the car radio 15 to the module 1. The module 1 supplies messages on its state, on errors, and on the processing of commands in return, which messages can be shown on the display 12.

FIG. 3 is a block diagram of the internal construction of a module 1 for reading CDs or DVDs. The drive unit 3 proper is formed by the drive for rotating the CD/DVD, the optical data pick-up unit 18 with a laser diode, lenses, and lens actuators for adjusting the focusing and tracking, a photodiode array for the multiple-field measurement for determining the focusing and tracking quality, and a radial drive for the data pick-up unit 1. The decoder IC 4 provides the channel decoding of the read data (for example EFM demodulation and error correction) and carries out an error interpolation, if necessary, and also controls the lens actuators for safeguarding an optimum focusing and tracking on the basis of the values of the multiple-field measurement. In the embodiment shown, the processor arrangement comprises the decoder IC 4 (for example a Philips PhonIC), a buffer memory 17, a DSP 5 (for example a DA 150 from TI) for digital data processing, and a digital/analog converter unit 7. In the embodiment shown here, the DSP 5 has a decoder region 16 into which a block decoding program can be loaded from the memory arrangement 6. In an alternative embodiment, a dedicated DSP is provided for the block decoding, or there is a fixedly programmed processor. Furthermore, the DSP 5 may carry out the MP3 decompression of MP3 compressed audio data. The necessary programs for block decoding and for MP3 decoding are stored in the memory arrangement 6 in a non-volatile manner and are loaded into the DSP 5 either upon switching-on of the module or upon demand. The DSP may be dimensioned such that it can load only one program at a time.

On an audio CD, audio data are laid down consecutively on a spiraling track from the inside to the outside (this relates either to the process of manufacturing an audio CD, for example with molded pits, or a corresponding writing process on a CD-R or CD-RW for the manufacture of an audio CD). A table of contents (TOC), in which information is laid down on the CD and on the individual audio data sequences, is present before the start of the actual audio data on the CD. In this TOC, for example, the absolute moment of the start of each audio data sequence can be found. This start time information is given in minutes (min), seconds (s), and frames (fra), one frame being one seventy-fifth of a second. A frame on a standard audio CD is composed of 98 fundamental 588-bit frames. Consecutive audio data are first interleaved and subsequently error-coded by the CIRC method. A further eight control bits are added to each block of 192 payload data bits and 64 error correction bits. Such a data block is subjected to an Eight-to-Fourteen Modulation (EFM) in which each eight-bit word is converted into a fourteen-bit word. Three coupling bits are joined to each fourteen-bit word, and finally each fundamental frame is provided with 24 synchronization bits, which results in a total of 588 bits. The information (min, s, fra) is also denoted a pointer, because the start of a data sequence can be unequivocally defined thereby (the time information in min, s, fra is incorporated in 98 control bits in each frame). Furthermore, the running time information for each audio data sequence can be calculated from the information in the TOC.

Data for a navigation system or compressed audio data are laid down on a CD in accordance with the CD-ROM standard (Yellow Book Standard). Since it should be possible to reconstruct ROM data fully also in the case of minor scratches on the CD, there is an additional coding in addition to the channel coding described above. Instead of 192 payload data bits, blocks (sectors) of 2048 payload data bits are defined, which lead to a total of 2352 bytes per sector in combination with error correction data and other additional information. This corresponds to the payload data bits of 98 fundamental frames. The 2352 bytes of a sector are subdivided into 98 fundamental frames, as are the audio data, and are subjected to the same error coding and EFM, so that CD-ROM data can work with a double error correction: of the channel coding and of the block coding. ROM data are laid down in a ROM data sequence structure. A ROM data sequence structure has its own table of contents (the so-called Volume Descriptor) and at least one data sequence. A ROM data sequence is characterized as such in the TOC of the CD. There is only one ROM data sequence structure on a standard CD-ROM. A ROM data sequence structure here usually comprises several data sequences arranged in a hierarchical structure, but these are not indicated in the TOC of the CD.

The start position of a data sequence on a CD-ROM can be indicated not only by means of a pointer, but also as an address (the so-called Logical Block Address—LBA). Address 0 starts at 2 s in a standard manner, i.e. at (0 min, 2 s, 0 fra). Address 1 then lies at (0 min, 2 s, 1 fra). This means that the addresses are exactly defined at frame level. The start time of a data sequence on a CD-ROM may alternatively be indicated by an address that can be readily calculated from the pointer information.

After a CD-ROM has been inserted, it is recognized from the TOC that it is a CD with a ROM data sequence structure. This is followed by reading of the Volume Descriptor. Information from the Volume Descriptor is stored in the memory arrangement 6. It may suffice for a CD-ROM with navigation data to store only the names of the various data sequences and their start addresses. In certain cases the number is too large for storage in the memory arrangement 6. In such a case, the information from the Volume Descriptor is transmitted to the navigation system. The latter information may also be requested by the navigation system itself. The navigation system requires these decoded data from the CD-ROM during its operation. According to the invention, decoded data are requested from the module. The decoding is not carried out in the navigation system. To read the coded data from the CD, the processor arrangement of the module requires the address of the data, so that the data pick-up unit can be moved to this location.

If the address is determined in the navigation system, the module, upon receiving a “GET DATA xxxx” command, must move the data pick-up unit only to the address “xxxx” and read and decode the data starting from this address. If the address is determined in the module, i.e. in that the table of contents information is stored in the memory arrangement, a reduced data exchange with the navigation system will take place after insertion of the data CD. Data can be called up more quickly. The data request can then take place by means of a high-level command. For example, if the data of the navigation system are stored in data sequences whose names correspond to the geographical positions, the navigation system can call up the data by means of a “FILEOPEN nnnn” command because of its knowledge of the geographical location where the user and his/her vehicle are present. “nnnn” here is the name of the requested data sequence. It is not necessary for the navigation system to know where this is located on the data CD. The module then accesses the table of contents information and seeks the data sequence with the name “nnnn”. The start address of the data sequence on the CD is also stored in association with this data sequence. Another high-level command is, for example, the “FILESEEK yyyy” command, upon reception of which the data pickup unit jumps over a distance corresponding to “yyyy” frames within the data sequence and starts reading again from the new position.

Data call commands are provided with an identifier according to the invention, because the module can still send data after the navigation system has transmitted its new request. Accordingly, the navigation system must be capable of distinguishing between data belonging to the previous request and data belonging to the current request. The module uses the identifier of the request command when sending the data, so that the sent data can be unequivocally identified. The identifier may be, for example, an eight bit long value that is incremented.

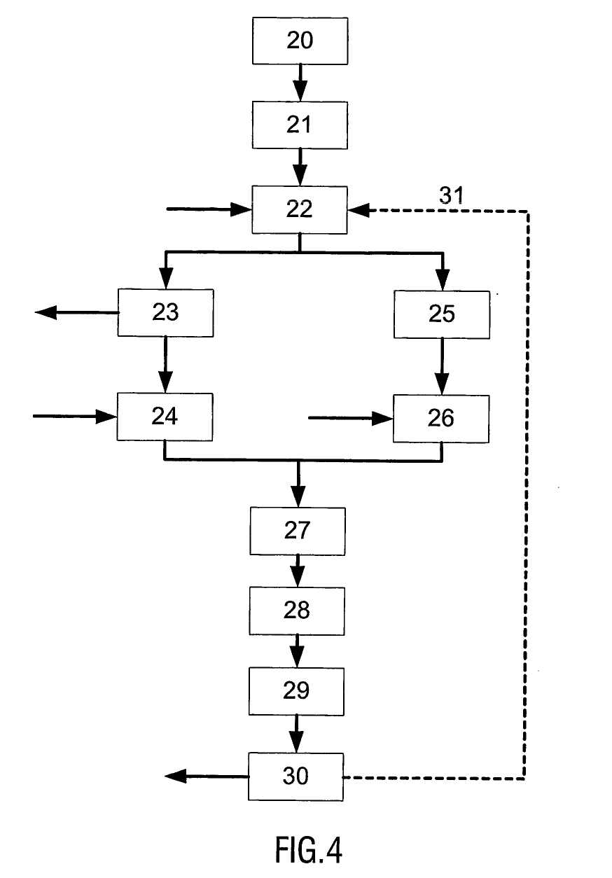

During operation of a module according to the invention, the procedure may be as follows, as shown in FIG. 4:
1. A CD-ROM with navigation data is inserted (step 20).
2. The TOC and the Volume Descriptor (VD) are read. The navigation data CD is recognized as such (step 21).
3. If the module has a programmable processor, the program for block decoding is read from the memory arrangement and is loaded into the programmable processor (step 22).
4. Depending on the embodiment of the module or as provided by the navigation system:
   a. the information from the TOC and the VD is sent to the navigation system (step 23), or
   b. the information from the TOC and the VD is stored in the memory arrangement of the module (step 24).
5. Depending on the option from 4.:
   a. following 4.a, a command “GET DATA xxxx” with the identifier “0” is sent by the navigation system to the module, and the processor arrangement receives the command (step 25), or
   b. following 4.b, a command “FILEOPEN nnnn” with the identifier “0” is sent by the navigation system to the module, and the processor arrangement receives the command. The processor arrangement accesses the memory arrangement and finds the information on the data sequence having the name “nnnn”. The address “xxxx” of the data sequence is read from the memory arrangement (step 26).
6. The processor arrangement controls the data pick-up unit such that the data pick-up unit is moved to the physical start of the data at address “xxxx” (step 27).
7. The coded data are read from the CD and passed on to the DSP for decoding, or they are loaded into a buffer memory (for example a FIFO) until the latter is full. The degree of occupation of the FIFO is checked, and further data are requested if the occupation is below a certain level (approximately 50%) (step 28).
8. The coded data passed on from the buffer memory to the DSP are decoded by the decoding function implemented by the decoding program (step 29).
9. The decoded data are provided with the identifier “0” and sent to the navigation system. Instead of sending the data, it is also possible to put them into intermediate storage in a further buffer memory, from which the navigation system requests the decoded data. Depending on the embodiment of the module, the address at which the data were read is additionally assigned to the data. The data are then made available in defined data packets of a given length, or the data exchange is controlled by a further parameter which indicates the length of the next data packet (step 30).
10. The navigation system requests further data. A corresponding command is sent to the module, as sub 5. The command contains the new identifier “1”. The subsequent steps 6 to 9 are carried out once more. Depending on the embodiment, the coded data still present in the buffer are rejected and not decoded, or the buffered data are decoded and transmitted so as to utilize the possibility that the requested data with identifier “1” are among those already read (indicated with the broken-line arrow 31).

The commands “GET DATA” and “FILEOPEN” are received through few connecting lines via a first serial bus (command bus) in an embodiment of the module, and the coded data are sent via a second serial bus (data bus). Besides one or two clock lines per bus, which serve to synchronize the transmitter and receiver, no further lines are required for the exchange of commands and data. This results in a module with a small number of connecting lines, i.e. a module of low cost and with a number of lines optimized for the field of automobiles. The use of a serial bus for the data exchange requires a suitable data exchange protocol. Thus a header of given length may be sent ahead of the actual data, in which header, for example, the identifier of the data request command and/or the current address from which the data were read are present. The next data packet may be, for example, always of the same length, or the header contains information on the length of the subsequent data packet. Other protocol characteristics obvious to those skilled in the art should be regarded as included herein.

1. A module for reading data carriers, with a processor arrangement and a reading unit,
wherein the module is designed for incorporation in a data processing device,
wherein addressable coded data are stored on the data carrier, and
wherein the processor arrangement comprises a decoding function and is for this purpose designed for
receiving a request, characterized by an identifier, for decoded data which are stored in coded form on the data carrier,
controlling the reading unit such that the requested data, defined by a start address, are read in the coded form from the data carrier,
converting the coded data into decoded data by means of the decoding function, and
making the decoded data, characterized by the identifier, available.

2. A module as claimed in claim 1, characterized in that the processor arrangement is designed for characterizing the decoded data by means of the current address from which the coded data were read from the data carrier.

3. A module as claimed in claim 1, characterized in that the processor arrangement is designed for receiving the start address immediately along with the request.

4. A module as claimed in claim 1, characterized in that the module comprises a memory arrangement,
wherein said memory arrangement is designed for storing table of contents information of the data carrier, and
wherein the processor unit is designed for deriving the start address from the request by using the table of contents information.

5. A module as claimed in claim 1, characterized in that the processor arrangement is designed for receiving the request characterized by an identifier via a first serial bus and for making available the decoded data characterized by the identifier via a second serial bus.

6. A module as claimed in claim 1, characterized in that the module comprises a memory arrangement, and in that the processor arrangement is designed for loading a decoding program from the memory arrangement, which program carries out the decoding function on a programmable processor.

7. A module as claimed in claim 1, characterized in that the data processing device is a car radio or a navigation system or a combined car radio/navigation system.

8. A data carrier playback device, in which a module according to claim 7 is incorporated.
